(19) United States
(12) Patent Application Publication
(10) Pub. No.: US 2014/0006705 A1
(43) Pub. Date: Jan. 2, 2014

(54) METHOD OF GENERATING MEMORY ADDRESSES AND REFRESH POWER MANAGEMENT CONTROLLER

(71) Applicant: SAMSUNG ELECTRONICS CO., LTD., Suwon-Si (KR)

(72) Inventors: Haksoo YU, Seongnam-si (KR); Chulwoo PARK, Yongin-si (KR); Joosun CHOI, Yongin-si (KR)

(73) Assignee: SAMSUNG ELECTRONICS CO., LTD., Suwon-Si (KR)

(21) Appl. No.: 13/835,077

(22) Filed: Mar. 15, 2013

(30) Foreign Application Priority Data
Jun. 29, 2012 (KR) 10-2012-0071241

(51) Int. Cl. G11C 11/406; G06F 3/06

(52) U.S. Cl. CPC G11C 11/40607; G06F 3/0625
USPC 711/106; 711/156; 711/158

(57) ABSTRACT

A method for managing operation of a memory includes determining a status of data stored at a memory address, assigning a code based on the status of the data, and selectively performing a power management operation for an area of a memory that includes the memory address based on the code.

### CROSS-REFERENCE TO RELATED APPLICATIONS

This U.S. non-provisional patent application claims priority under 35 U.S.C. §119 of Korean Patent Application No. 10-2012-0071241, filed on Jun. 29, 2012, the entire contents of which are hereby incorporated by reference.

### BACKGROUND

1. Field

The present inventive concept herein relates to power saving of semiconductor memories, and more particularly, to a method of generating a DRAM address to reduce power being consumed when a refresh operation is performed and a refresh power management system.

2. Description of Related Art

Power management continues to be a focus of device designers. Many of these devices perform memory refresh operations in various operational modes. These operations may be performed for various types of memories. Unfortunately, refresh operations consume substantial power and therefore improved refresh power management is a consideration, especially for battery-driven devices.

Further, as power consumption of a memory increases, research and development of memory power management has been consistently been performed. A comparatively short time burst operation and a long time idle state form a large percentage of an operation pattern of volatile semiconductor memory (e.g., a dynamic random access memory DRAM) used in a mobile application. In an idle state, a DRAM performs a self-refresh and in a normal operation state, a DRAM performs an auto refresh. Thus, power consumed in a refresh operation during a normal operation state or an idle state occupies most of the whole power. Thus, a DRAM applied to a mobile device needs a more effective refresh power management.

### SUMMARY

In accordance with one example embodiment of the inventive concept, a memory address generation method includes generating an address corresponding to an area of a memory to be accessed and generating an address to be transmitted to the memory by assigning a semantic code to be used in controlling performance of a refresh operation for the address, and to thereby effect power management for the memory.

In accordance with another example embodiment of the inventive concept, a refresh power management system includes an operating system configured to provide page free information in or for a physical address, a controller configured to generate a memory address by assigning a semantic code for use in determining whether or not a refresh operation is to be performed according to the page free information in the physical address, and a memory controlled to selectively perform a refresh operation on a memory page according to the assigned semantic code.

In accordance with another example embodiment of the inventive concept, a method for managing operation of a memory includes determining a status of data stored at a memory address, assigning a code based on the status of the data, and selectively performing a power management operation for an area of a memory that includes the memory address based on the code.

The assigning may include assigning the code to a number of bits of the memory address, where the number is fewer than all bits of the memory address. The code may include first information indicating a type of data corresponding to the memory address and second information indicating a type of operation for the data at the memory address. The type of operation may be write operation for the data at the memory address.

The power management operation may be a refresh operation to be performed for the area including the memory address. And, the area including the memory address may correspond to a row unit, column unit, or bank unit of the memory.

The method may include sending information corresponding to the code to a buffer of the memory according to a write command, and/or sending information corresponding to the code to a buffer of the memory according to a free charge command.

The method may include storing tag information corresponding to the code in a tag memory, where the tag information indicates whether the power management operation is to be performed for the area including the memory address.

In accordance with another example embodiment of the inventive concept, a method for controlling storage of data includes setting first information for a first memory address, setting second information for a second memory address, and selectively controlling a power management operation for the first memory address based on the first information and the second memory address for the second information. The first information indicates that data of the first memory address has a first priority, the second information indicates that data of the second memory address has a second priority, and the power management operation is performed for the first memory address and suspended for the second memory address.

The first memory address and the second memory address may be included in a same memory, and the power management operation may include a refresh operation.

The first priority may be greater than the second priority, and the second priority may correspond to fault tolerant data.

The first information may indicate a first memory operation, and the second information may indicate a second memory operation different from the first memory operation, wherein the first memory operation includes a write operation. The first information may be included in the first address and the second information may be included in the second address.

The method may further include generating first tag information and second tag information, where the first tag information is generated from the first information and the second tag information is generated from the second information and wherein the first tag information and second tag information have fewer bits than respective ones of the first information and the second information. The first information and the first tag information may be included or appended to the first memory address, and the second information and second tag information may be included in or appended to the second memory address.

The first memory address and the second memory address may be physical or virtual addresses, and the power management operation may be coincident with an active state of a host device of memory including the first and second memory addresses.

In accordance with another example embodiment of the inventive concept, a controller includes an interface coupled to a memory configured to store data and a controller configured to assign a code corresponding to an address of the memory and to selectively control performance of a power management operation for an area of the memory that includes the memory address, the controller to assign the code based on a status of stored data stored corresponding to the address. The interface may be within the controller or may be external to and coupled to the controller by a signal line or other connection.

The controller may be configured to include the code in the memory address or to append the code to the memory address, and the code may be sent to a buffer of the memory according to a write command.

The system may further include a tag memory configured to store tag information corresponding to the code, where the tag information indicates the status of the stored data corresponding to the memory address in fewer bits than the code. The memory address may be a physical or virtual address, and the power management operation may include an auto-refresh or self-refresh operation.

### BRIEF DESCRIPTION OF THE DRAWINGS

These and/or other aspects of the invention will become apparent and more readily appreciated from the following description of the embodiments, taken in conjunction with the accompanying drawings of which:

FIG. 1 shows an example of a refresh power management system in accordance with inventive concepts.

FIG. 2 shows control information for performing a refresh operation.

FIG. 3 shows an example embodiment of a control system for FIG. 1.

FIG. 4 shows examples of addresses in connection with FIG. 3.

FIG. 5 shows an example of a memory refresh operation.

FIG. 6 shows an example of a semantic communication protocol.

FIG. 7 shows a timing diagram for semantic code transmission.

FIG. 8 shows an example of tag bit for the semantic code of FIG. 7.

FIG. 9 shows another example of a control system for FIG. 1.

FIG. 10 shows another example of a control system for FIG. 3.

FIG. 11 shows an example application of the inventive concept to a memory system.

FIG. 12 is a block diagram illustrating an application example of the inventive concept applied to a mobile device.

FIG. 13 is a block diagram illustrating an application example of the inventive concept applied to an optical I/O schema.

FIG. 14 shows an example application to a through-silicon via (TSV).

### DETAILED DESCRIPTION OF EXAMPLE EMBODIMENTS

Inventive concepts will now be described more fully hereinafter with reference to the accompanying drawings, in which example embodiments of the inventive concept are shown. The advantages and features of the inventive concepts and methods of achieving them will be apparent from the following example embodiments that will be described in more detail with reference to the accompanying drawings. It should be noted, however, that the inventive concepts are not limited to the following example embodiments, and may be implemented in various forms. Accordingly, the example embodiments are provided only to disclose the inventive concepts and let those skilled in the art know better understand the inventive concepts. In the drawings, embodiments of inventive concepts are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal example views of the inventive concept. Accordingly, shapes of the example views may be modified according to manufacturing techniques and/or allowable errors. Therefore, the embodiments of the inventive concept are not limited to the specific shape illustrated in the example views, but may include other shapes that may be created according to manufacturing processes. Areas exemplified in the drawings have general properties, and are used to illustrate specific shapes of elements. Thus, this should not be construed as limited to the scope of the inventive concepts.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Example embodiments of aspects of the present inventive concept explained and illustrated herein include their complementary counterparts. The same reference numerals or the same reference designators denote the same elements throughout the specification.

Moreover, example embodiments are described herein with reference to cross-sectional illustrations and/or plane illustrations that are idealized example illustrations. Accordingly, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

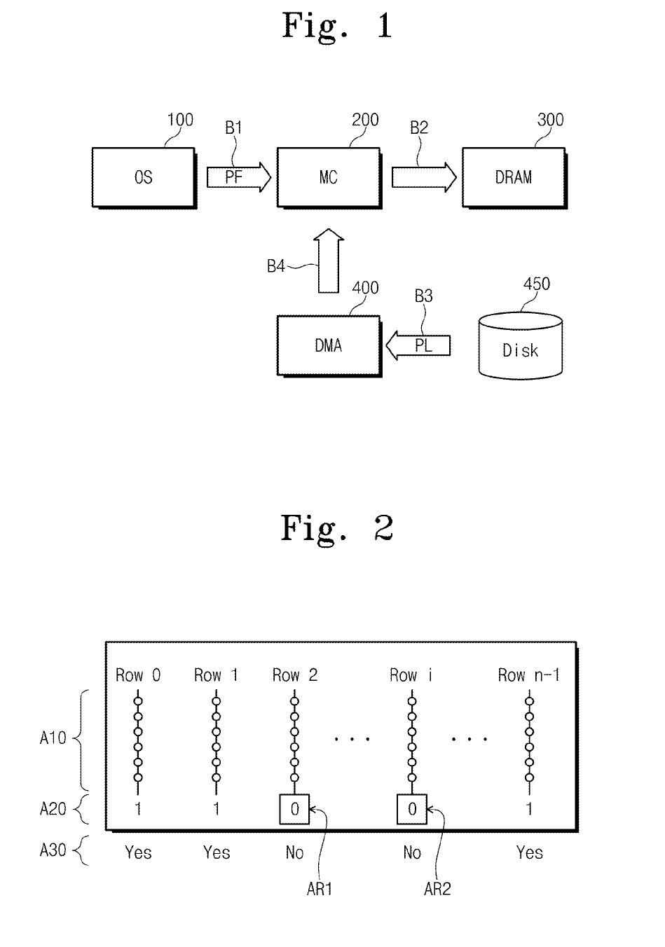

FIG. 1 shows an example embodiment of a refresh power management system which includes an operating system 100, a controller 200, a memory 300, a direct memory access (DMA) unit 400, and a disk 450.

Page free (PF) information which the operating system 100 generates is included in a line B1 and is sent toward controller 200 from the operating system 100. Program load information is included in a line B3 and is sent toward DMA 400 from disk 450. A write command and a semantic code are included in a line B2 and are sent toward memory 300 from controller 200. The write command and semantic code may be used in a power management of the memory 300. The memory may be a volatile memory including but not limited to a DRAM.

The DRAM 300 performs a refresh operation depending on the semantic code. The refresh operation may be performed, for example, when a host device is in an active state. In accordance with example embodiments, the refresh operation is selectively performed based on tag information stored in a memory page. As a result, refresh power may be reduced at least for a memory page in which a refresh operation is selectively not performed. To reduce refresh power, a level of importance of data and/or a refresh status may be assigned to an address as a semantic code. FIG. 2 shows an example of control information that may be used for performing a selective refresh operation, e.g., determining whether or not a refresh operation is to be performed on a memory page. In this example, A10 indicates a row address, A20 indicates a tag bit, and A30 indicates whether or not a refresh operation is to be performed. Because a tag bit of Row 2 is set to “0” as indicated by an arrow AR1, the DRAM 300 does not perform a refresh operation when Row 2 becomes eligible for a refresh operation. Similarly, because a tag bit of Row i is set to “0” as indicated by an arrow AR2, the DRAM 300 does not perform a refresh operation when the Row i becomes an object of refresh operation. That is, when a refresh operation is to be considered for a row address with a tag bit set to re,” a refresh operation is skipped.

Conversely, a tag bit of Row 1 is set to “1.” Based on this bit value, DRAM 300 performs an auto-refresh operation or a self-refresh operation when the Row 1 becomes eligible for a refresh operation. While the tag bit is indicated to be one bit in length, in other embodiments tag bit information may be assigned to have a plurality of bits, for example, to designate whether a certain type of refresh and/or other operation is to be performed.

Thus, through the setting of these bit values, important (e.g., critical, priority, or favored) data that should not be dissipated may be stored in a memory area in which a refresh operation should be performed, e.g., a memory page or, for instance, all memory cells connected to one word line. On the other hand, less important data or free data may be stored in a memory area or page for which a refresh operation is not performed. In accordance with example embodiment, a state value of a tag bit may be set depending on the semantic code generated according to the page free information and/or program load information of FIG. 1.

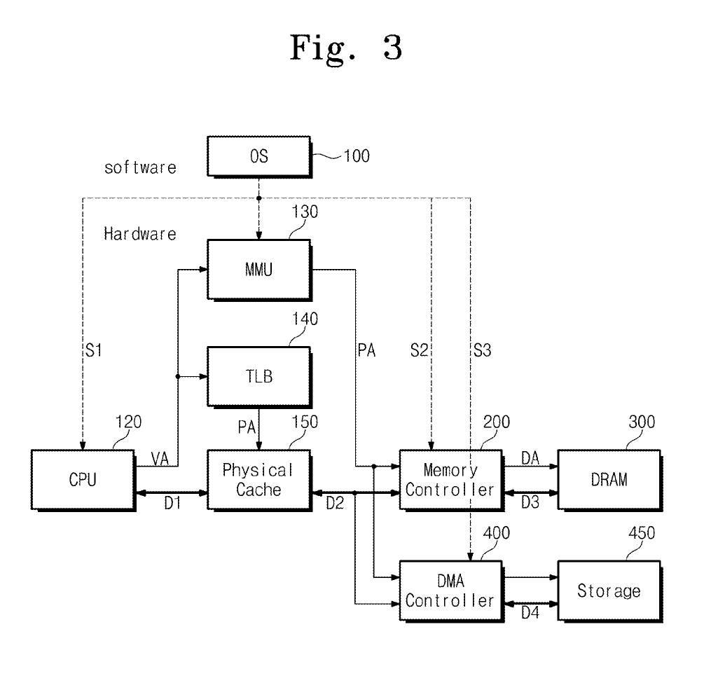

FIG. 3 shows example embodiment of a control system that may perform refresh power management for FIG. 1. As shown, operating system 100 is connected to a CPU 120, a memory management unit 130, a memory controller 200 and a DMA controller 400 which communication based on software instructions through lines S1, S2, S3 and S4.

The CPU 120 generates a virtual address VA according to software of the operation system 100 to apply the virtual address VA to the memory management unit 130 and a translation lookaside buffer (TLB) 140. The translation lookaside buffer generates a physical address PA to be applied to a physical cache 150.

The memory controller 200 that operates under operation system 100 receives the physical address PA to generate a DRAM address (DA). The generated DRAM address is applied to the DRAM 300. Lines D1, D2, D3 and D4 are data lines through which data is received and transmitted.

If the operating system 100 recognizes page free information, CPU 120 generates a virtual address VA by an operation through the line S1. The virtual address VA is converted into the physical address PA by the MMU 130. Page free information may be assigned to the physical address PA as a semantic code.

The memory controller 200 receives the physical address PA. When generating an address corresponding to a memory page to be accessed among a plurality of memory pages, the memory controller assigns a semantic code to be used to determine whether or not a refresh operation is performed to the address according to page free information included in the physical address PA to generate a DRAM address DA.

Thus, the DRAM 300 selectively performs a refresh operation on the memory page in an auto-refresh operation mode or a self-refresh operation mode according to a semantic code assigned to the DRAM address. Because a refresh operation on a memory page that does not need a refresh operation is skipped by selective performance of refresh operation, refresh power consumption is reduced.

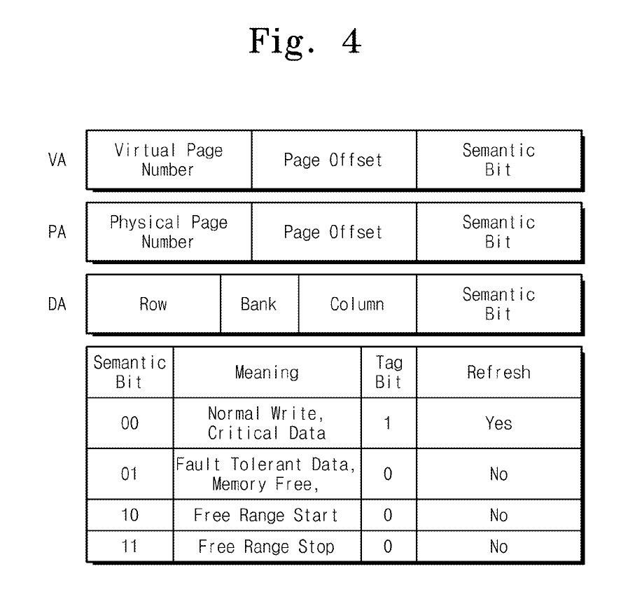

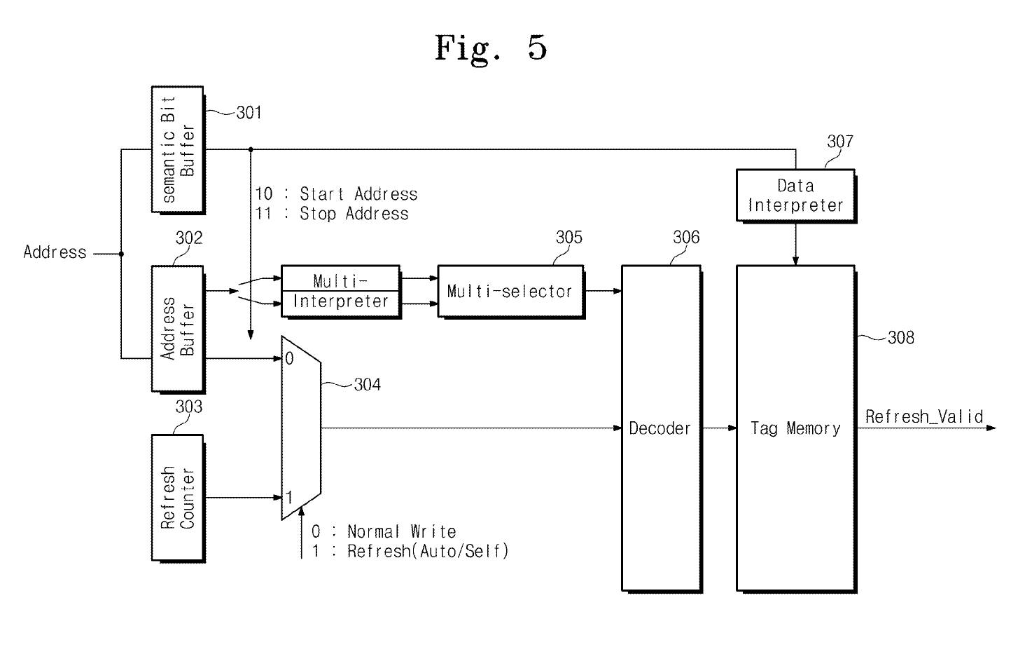

FIG. 4 shows various addresses that may be used in FIG. 3. These addresses include a virtual address VA which may include a virtual page number, page offset information, and semantic bit information of one or more bits. A physical address PA may include a physical page number, a page offset and semantic bit information. A DRAM address DA may include a row address, a bank address, a column address and a semantic bit.

As further shown in FIG. 4, the semantic bit information may be 2 bits in length. In this example, a semantic code is “00” indicates a write operation for data having a status of important data. When semantic code “00” is decoded, a tag bit may be set to 1, to indicate that a refresh operation is to be performed.

That is, a tag bit having a value of 1 may be generated when the semantic code is decoded. Information of the tag bit is generated by a DRAM receiving the semantic code. The tag bit information may indicate whether a refresh operation is to be performed on a corresponding memory area or this information may be stored, for example, in a tag memory inside the DRAM.

In example embodiment, the tag bit is a bit subsequent to the semantic code and may be generated in concurrence with the DRAM address (DA). And, performance of an auto-refresh operation or a self-refresh operation on the memory area may be determined according to the tag information of at least one bit stored in the tag memory.

A semantic code having a value of 01 may indicate fault tolerant data and may mean memory free. When the semantic code 01 is decoded, a tag bit may be set to 0. This 0 value may indicate that a refresh operation is not to be performed. In a memory free case, it may not be necessary to perform a refresh operation and therefore refresh power may be saved. Similarly, tag bit 0 may be a bit subsequent to the semantic code and may be generated in concurrence with DRAM address (DA). Tag bit 0 may be generated when the semantic code is decoded in the DRAM and may be stored in the tag memory.

A semantic code having a value of 10 may indicate free range start. When a semantic code 10 is decoded, a tag bit of 0 may be set. The 0 tag bit may indicate that a refresh operation is not to be performed. Even in the case of a free range start, a refresh operation will not be performed to save refresh power.

A semantic code having a value of 11 may indicate a free range stop. When semantic code 11 is decoded, a tag bit 0 may be set. The 0 tag bit may indicate a refresh operation is not to be performed. Even in the case of a free range stop, a refresh operation will not be performed to save refresh power.

In example embodiment, one or more semantic bits may be assigned to low-order bits among bits of the DRAM address or may be assigned to high-order bits among bits of the DRAM address as extra address bit(s).

The semantic code provides an indication of the properties of data for a memory area of the DRAM and, for example, may be used a code to indicate whether a refresh operation is to be performed on the memory area or not. The memory area may correspond to a row unit, a column unit, or a bank unit of the DRAM. The semantic code may be transmitted to an address buffer of the DRAM 300 when a write command is applied or a free charge command is applied.

FIG. 5 shows one arrangement for controlling the performance of a refresh operation of the DRAM of FIG. 1. This arrangement includes a semantic bit buffer 301, an address buffer 302, a refresh counter 303, an operation mode selector 304, a multi selector 305, a decoder 306, a data interpreter 307 and a tag memory.

The semantic bit buffer 301 can receive an address bit of high-order 2 bits among a row address of 15 bits as a semantic code.

The data interpreter 307 recognizes that a refresh operation is to be performed when a semantic code having a 00 value is received and recognizes that a refresh operation is not to be performed when semantic codes are received having the following values: 01, 10, or 11.

When receiving a decoded address from the decoder 306, the tag memory 308 stores a tag bit value in its internal storage area according to the semantic code. Thus, when a corresponding row address is applied and a refresh operation begins, if a tag bit of the corresponding row address of tag memory 308 is stored as a 0 value, a refresh operation is not performed on the corresponding row address. That is, a refresh operation is not performed.

If a mode control signal is applied as 1, the operation mode selector 304 selects a counting output of the refresh counter 303 to provide the counting output to the decoder 306. If a mode control signal is applied as 0, the operation mode selector 304 selects an output of the address buffer 302 to provide the output to the decoder 306.

If the semantic code has a value of 10, a start address is indicated; and if the semantic code is 11 a stop address is indicated. Based on the start address and stop address, a plurality of row units can be set at one time for performing a refresh operation without setting every row unit.

The semantic code can be set for a row unit, a column unit, a memory block or a bank unit. In set for a bank unit, a semantic code having a value of 01 may result in a tag information bit with a value of 0 being stored in the tag memory. In this case, a refresh operation of the corresponding bank will be skipped when a refresh beginning mode of the corresponding bank is eligible to be performed.

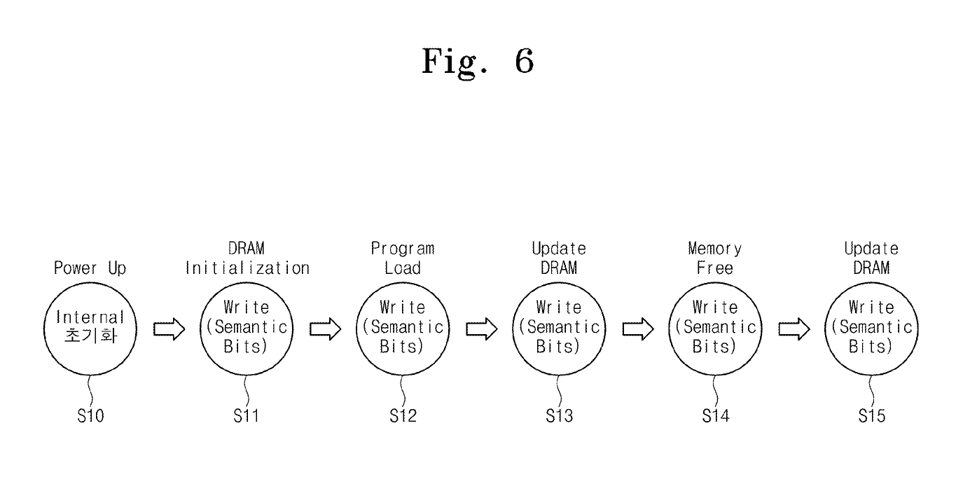

FIG. 6 shows an example of a semantic communication protocol based on a write request in accordance with an operation of FIG. 1. In this example, S10 represents an internal initialization step on power-up, S11 represents an initialization step of the DRAM, S12 represents performance of program load, S13 represents a DRAM update step, S14 represents a memory free, and S15 represents a DRAM update step.

In FIG. 6, semantic communication protocols are based on a write request. In example embodiment, program load by an operating system (OS) or DRAM page free information is updated in real time. Use of the protocols using for the write request enables a real-time update. A semantic communication protocol and a normal read or normal write operation may be treated without discrimination and are scheduled by a memory controller. In the case of program load, the memory controller may transmit a DRAM address including a semantic code when a write command is transmitted. As a result, a real-time update in the DRAM may be accomplished.

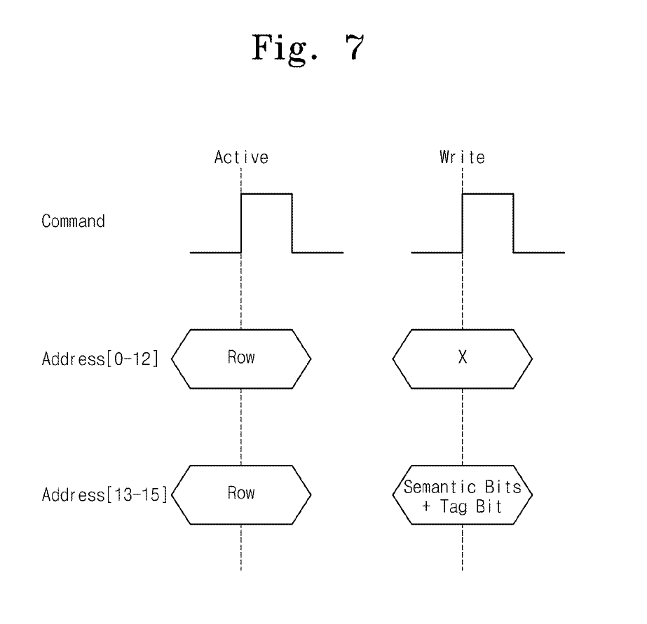

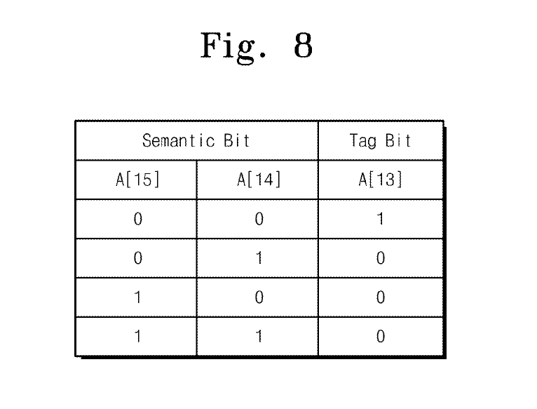

FIG. 7 shows an example of a timing diagram of semantic code transmission in accordance with an operation of FIG. 1. When an active command is transmitted, an occurrence time of row address (ADD 0˜12) and an extra row address (ADD 13˜15) is shown. When a write command is transmitted, an occurrence time of row address (ADD 0˜12) and an extra row address (ADD 13˜15) is shown. When a write command is transmitted, the semantic code and a tag bit may be assigned to the extra row address (ADD 13˜15). In FIGS. 7 and 8, an example is illustrated which the tag bit is generated together with the semantic code to be transmitted to the DRAM.

FIG. 8 shows an example of tag bits corresponding to the semantic codes for FIG. 7. As shown, semantic codes are assigned as an extra address A14 and extra address A15 and the tag bit is assigned as an extra address A13.

A tag bit with a value of 1 indicates that a refresh operation is to be performed and a tag bit of 0 indicates that a refresh operation is not to be performed.

A semantic code having a value of 00 indicates a normal write and the status of corresponding data as important. When the semantic code 00 is decoded, the tag bit may be set to 1 indicating that a refresh operation is not to be performed.

A tag bit of 1 may be generated when the semantic code is decoded. That is, information of the tag bit is generated by a DRAM receiving the semantic code and information corresponding to the tag bit may indicate whether a refresh operation on an associated memory area is to be performed or not. The tag bit information may be stored in a memory area, for example, inside the DRAM. In accordance with example embodiment, a tag bit may be a bit subsequent to the semantic code and can be generated in concurrence with the DRAM address (DA).

Performance of an auto-refresh operation or self-refresh operation on a memory area may be determined according to the tag information of at least one bit stored in the tag memory.

A semantic code having a value of 01 indicates fault tolerant data and/or may correspond to or indicate memory free. When a semantic code having a value of 01 is decoded, a tag bit may be set to 0 to indicate a refresh operation is not to be performed. In a memory free case, the refresh operation is not performed to save refresh power. Similarly, a tag bit having a value of 0 may be a bit subsequent to the semantic code and may be generated in concurrence with the DRAM address (DA). The 0 tag bit may be generated when the semantic code is decoded in the DRAM and may be stored in the tag memory.

A semantic code having a value of 10 may indicate a free range start. When the semantic code 10 is decoded, a tag bit may be set to a value of 0 to indicate that a refresh operation is not to be performed. In the case of even free range start, a refresh operation therefore is not to be performed to save refresh power.

A semantic code 11 may indicate free range stop. When semantic code 11 is decoded, a tag bit may be set to a value of 0 to indicate that a refresh operation is not to be performed. In the case of even free range stop, a refresh operation is not to be performed to save refresh power.

The semantic bit may be assigned to low-order bits among bits of the DRAM address or may be assigned to high-order bits among bits of the DRAM address as an extra address bit.

The semantic code may provide in indication of the properties of data (whether the data is less important or more important) on a memory area of the DRAM and may be used a code to direct whether a refresh operation is to be performed on the memory area or not. The memory area may correspond to a row unit, a column unit, or bank unit or, otherwise, an address or range of addresses of the DRAM. The semantic code may be transmitted to the semantic bit buffer 301 (e.g., a kind of an address buffer of the DRAM) when, for example, a write command is applied or a free charge command is applied.

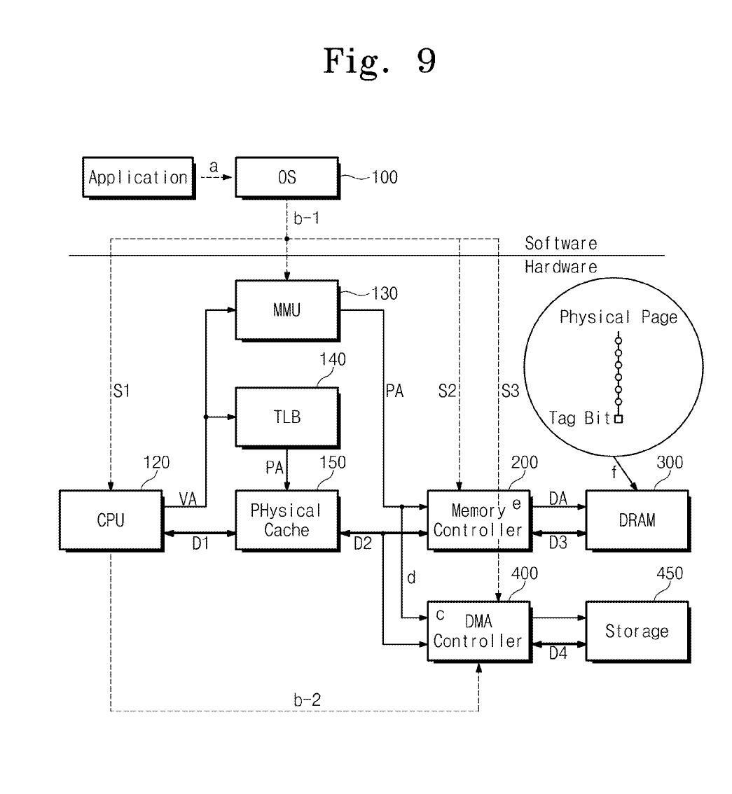

FIG. 9 shows another embodiment of a control system that may perform refresh power management for FIG. 1 In this embodiment, when a program is loaded, a scheme of transmitting importance of data to a DRAM is illustrated.

When an application is to be executed, a program stored in storage 450 in DRAM 300 may have to be loaded. When loading a program in the DRAM, operating system (OS) 100 may recognize the properties of the data and assign a corresponding semantic code to an address corresponding to the data.

More specifically, in this example embodiment, when an application is to be executed, a request for a program load is sent to the operating system (OS) through line (a). The CPU 120 operates through a software line (b-1) of the operating system, and the DMA controller 400 is initialized through a control line (b-2) of the CPU. The DMA controller assigns a semantic code to a physical address, and the physical address to which the semantic code is assigned is transmitted to the memory controller 200 through a physical address line (d).

The memory controller 200 receives the physical address including the semantic code to generate a DRAM address including the semantic code. The memory controller then applies the DRAM address to DRAM 300 when a write command or a DRAM free charge command is transmitted. The DRAM may interpret the semantic code in the DRAM address to store tag bit information indicating whether or not a refresh operation is to be performed in a tag memory like a reference character f.

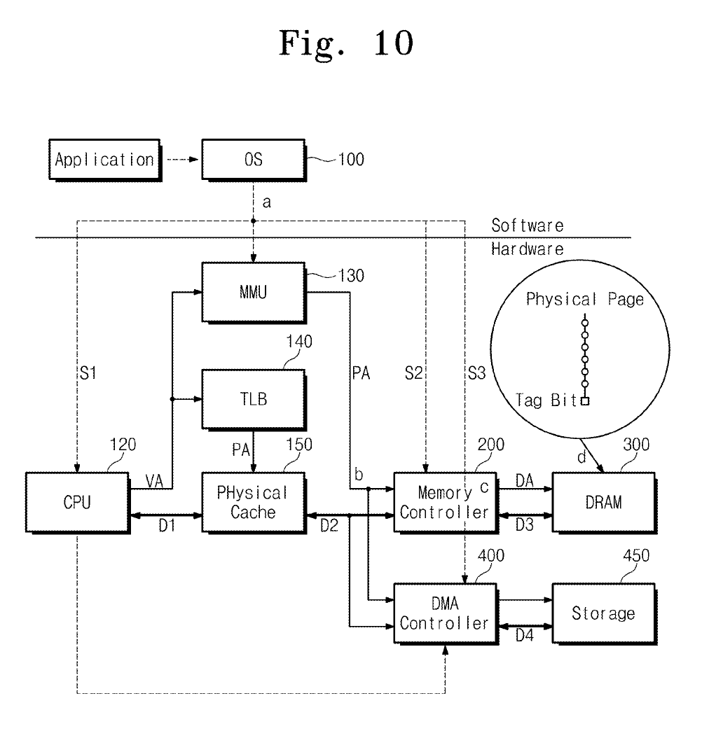

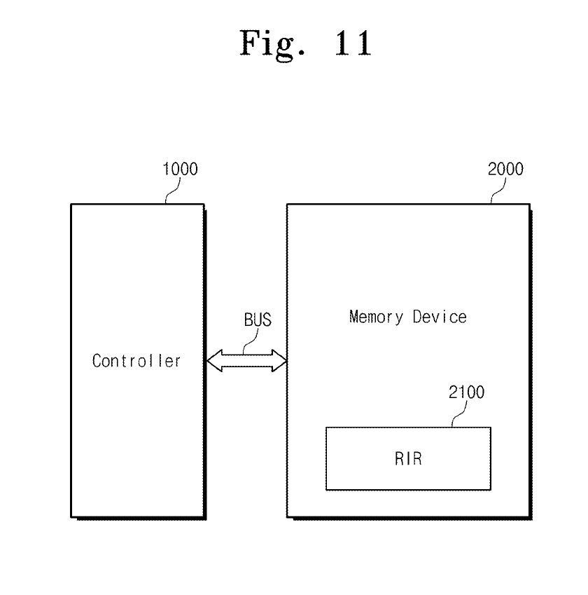

FIG. 10 shows another embodiment of a control system that may perform refresh power management for FIG. 1 In this embodiment, when updating free information in a page table, a scheme of updating the DRAM in real time is illustrated. More specifically, in a cache, when updating memory free information in a page table, a write operation is requested to the DRAM and refresh power can be managed by assigning semantic bit information (e.g., one or more bits) to a DRAM address being applied.

If a page table update phenomenon occurs, the software line (a) of the operating system 100 is activated. Accordingly, a semantic code is assigned to a physical address generated from a line (b). When a memory write operation is requested, a free range start address may be assigned as a semantic code “10”. A free range end address may be assigned as a semantic code “11”.

When a write command is transmitted or a free charge command is transmitted, the memory controller 200 applies a DRAM address. The semantic code is added to a part of DRAM address bit to be transmitted to the DRAM 300.

The DRAM interprets the semantic code in the DRAM address to store tag bit information to indicate whether or not a refresh operation is to be performed in a tag memory like a reference character d.

FIG. 11 shows an example application in which the memory system includes a controller 1000 and a memory device 2000. The memory device 2000 includes a refresh information register (RIR) 2100 which is related to a refresh operation in accordance with one or more embodiments.

The controller 1000 can apply a command, an address and write data to the memory device 2000 through a bus. A semantic code to be used in a power management of DRAM is assigned to the address. The refresh information register (RIR) 2100 decodes the semantic code to store the decoded semantic code in the inside thereof as tag information related to whether or not a refresh operation is performed. The memory device 2000 selectively performs a refresh operation according to the tag information when entering an auto-refresh mode or a self-refresh mode. Because consumption of refresh power is reduced, an operation performance of the memory system is improved.

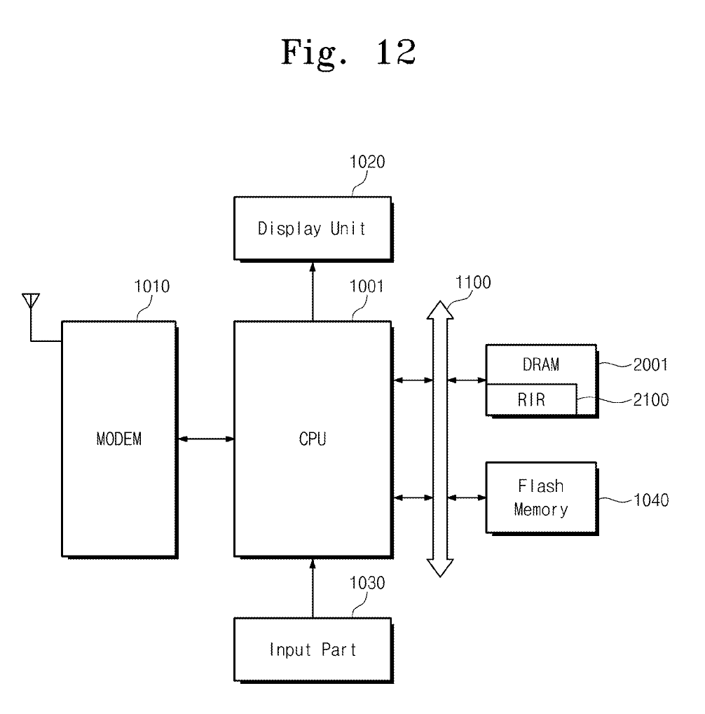

FIG. 12 shows another example application in which a mobile device includes a modem 1010, a CPU 1001, a DRAM 2001, a flash memory 1040, a display unit 1020 and an input part 1030. The CPU 1001, the DRAM 2001 and the flash memory 1040 may be manufactured or packaged in one chip, and DRAM 2001 and flash memory 1040 may be embedded in the mobile device.

In the case that the mobile device is a portable communication device, the modem 1010 performs a modulation demodulation function of communication data. The CPU 1001 controls an overall operation of the mobile device according to the preset program.

The DRAM 2001 is connected to the CPU 1001 through a system bus 1100 and functions as a main memory of the CPU 1001. The DRAM includes the refresh information register (RIR) 2100 which is related to a refresh operation in accordance with some embodiments of the inventive concept.

The CPU 1001 can apply a command, an address and write data to the DRAM 2001 through the system bus 1100. A semantic code to be used in a power management of DRAM is assigned to the address. The refresh information register (RIR) 2100 decodes the semantic code to store the decoded semantic code in the inside thereof as tag information related to whether or not a refresh operation is performed. The memory device 2000 selectively performs a refresh operation according to the tag information when entering an auto refresh mode or a self refresh mode. Because consumption of refresh power is reduced, operation performance and battery life of the mobile device can be improved.

The flash memory 1040 may be a NOR-type flash memory or a NAND-type flash memory.

The display unit 1020 may, for example, be a liquid crystal display having a backlight, a liquid crystal display having an LED light source, or an OLED. Moreover, the display unit 1020 may have a touch screen and may function as an output device for outputting an image such as character, number, picture, etc., in color.

The input part 1030 may be an input device including a number key, a function key, etc. The input part 1030 interfaces the electronic device with a person. The mobile device was described as a mobile communication device (e.g., smart phone, notebook computer, pod- or pad-type device, or any of a number of other devices), but in other embodiments the mobile device may be, for example, a smart card for storing account information or other data.

Moreover, the mobile device can connect a separated interface to an external communication device. The communication device may be a digital versatile disc (DVD) player, computer, set top box (STB), game machine, navigation system, a digital camcorder, etc. The mobile device may also include an application chipset, a camera image processor (CIS), and a mobile DRAM.

The DRAM 2001 chip and the flash memory 1040 can be mounted by various types of packages such as PoP (package on package), ball grid array (BGA), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), thin quad flatpack (TQFP), system in package (SIP), multi chip package (MCP), wafer-level fabricated package (WFP) or wafer-level processed stack package (WSP).

A flash memory may be another example or various kinds of nonvolatile storages may be used. The nonvolatile storage can store data information having various data types such as text, graphic, software code, etc.

Examples of the nonvolatile storage may include an electrically erasable programmable read-only memory (EEPROM), a flash memory, a magnetic random access memory (MRAM), a spin-transfer torque MRAM, a conductive bridging RAM (CBRAM), a ferroelectric RAM (FeRAM), a phase change RAM (PRAM) which is called an ovonic unified memory (OUM), a resistive RAM (RRAM), a nanotube RRAM, a polymer RAM (PoRAM), a nanotube floating gate memory (NFGM), a holographic memory, a molecular electronics memory device, or an insulator resistance change memory.

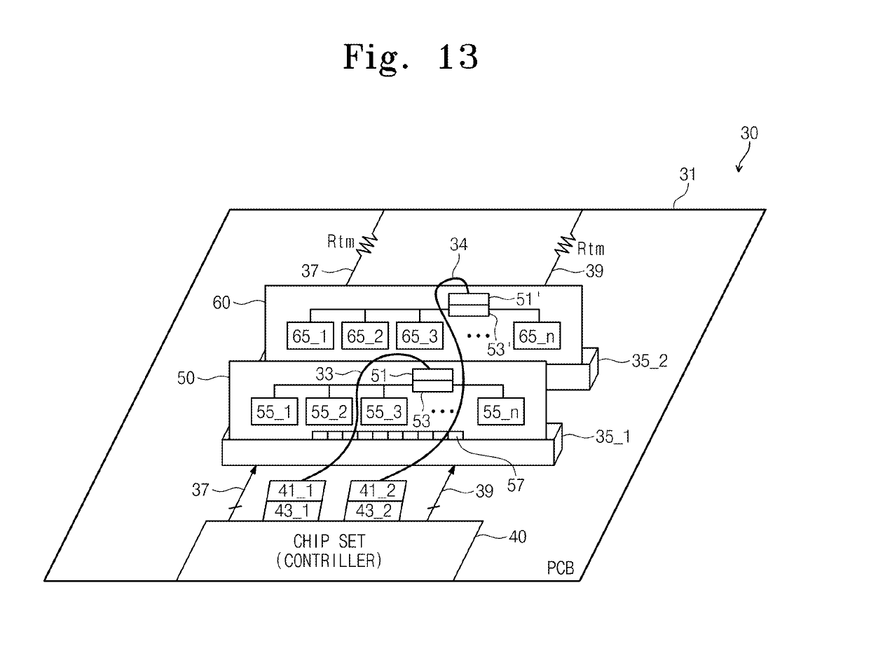

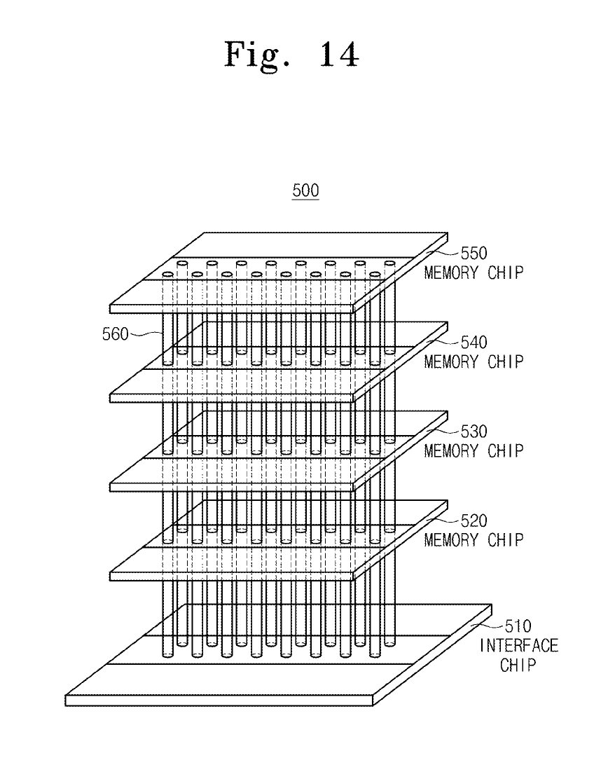

FIG. 13 shows an example application applied to an optical I/O schema. In this example, a memory system 30 adopting a high-speed optical I/O includes a chipset 40 which is a controller mounted on a PCB 31 and memory modules 50 and 60. The memory modules may be inserted into slots 35_1 and 35_2 installed on the PCB 31 respectively. Memory module 50 may include a connector 57, DRAM memory chips 55_1˜55_n, an optical I/O input part 51 and an optical I/O output part 53.

The optical I/O input part 51 may include a photoelectric conversion device for converting an optical signal being applied into an electrical signal, for instance, a photodiode. Thus, an electrical signal output from the photoelectric conversion device is received to the memory module 50. The optical I/O output part 53 may include a conversion device for converting an electrical signal output from the memory module 50 into an optical signal, for instance, a laser diode. If necessary, the optical I/O output part 53 may further include an optical modulator for modulating a signal output from a light source.

An optical cable 33 is in charge of an optical communication between the optical I/O input part 51 of the memory module 50 and an optical transmission part 41_1 of the chipset 40. The optical communication may have a bandwidth of several tens of gigabits per second or more. The memory module 50 can receive signals or data applied from signal lines 37 and 39 of the chipset 40 through the connector 57 and can perform a high speed data communication with the chipset 40 through the optical cable 33. Resistors Rtm installed in lines 37 and 39 are termination resistors.

A DRAM address generation schema for a refresh power management of the inventive concept can be applied to the memory system 30 adopting the optical I/O structure like FIG. 13. The DRAM memory chips 55_1˜55_n of the memory modules 50 and 60 can be selectively refreshed by a page unit, a column unit, or a bank unit according to a semantic code included in an address applied from the chipset 40 when entering a refresh operation. A refresh power management is effectively performed and thereby power saving can be accomplished.

FIG. 14 shows another example application example applied to a through-silicon via (TSV). This example includes a laminated-type memory device 500 and a plurality of memory chips 520, 530, 540 and 550 vertically stacked on an interface chip 510. A plurality of through-silicon vias (TSVs) are formed to pass through the memory chips.

A memory device of three-dimensional stack package-type vertically stacking a plurality of memory chips on the interface chip 510 using a TSV technology may have an advantage of high speed, low power consumption and/or miniaturization in at least one example embodiment, while simultaneously storing large amounts of data. In the case of the laminated-type memory device of FIG. 14, refresh power management may be effectively performed on DRAMs inside the plurality of memory chips 520, 530, 540 and 550.

According to one or more embodiments, because a refresh operation is not performed on a memory area that does not need a refresh operation, power saving is accomplished on a refresh operation mode.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A method for managing operation of a memory, comprising:
determining a status of data stored at a memory address;
assigning a code based on the status of the data; and
selectively performing a power management operation for an area of a memory that includes the memory address based on the code.

2. The method of claim 1, wherein the assigning includes:
assigning the code to a number of bits of the memory address,
wherein said number is fewer than all bits of the memory address.

3. The method of claim 1, wherein the code includes:
first information indicating a type of data corresponding to the memory address, and
second information indicating a type of operation for the data at the memory address.

4. The method of claim 3, wherein the type of operation is a write operation for the data at the memory address.

5. The method of claim 1, wherein the power management operation is a refresh operation is to be performed for the area including the memory address.

6. The method of claim 1, wherein the area including the memory address corresponds to a row unit, column unit, or bank unit of the memory.

7. The method of claim 1, further comprising sending information corresponding to the code to a buffer of the memory according to a write command.

8. The method of claim 1, further comprising sending information corresponding to the code to a buffer of the memory according to a free charge command.

9. The method of claim 1, further comprising:
storing tag information corresponding to the code in a tag memory,
wherein the tag information indicates whether the power management operation is to be performed for the area including the memory address.

10. A method for controlling storage of data, comprising:
setting first information for a first memory address;
setting second information for a second memory address; and
selectively controlling a power management operation for the first memory address based on the first information and the second memory address for the second information, the first information indicating that data of the first memory address has a first priority, the second information indicating that data of the second memory address has a second priority, and the power management operation is performed for the first memory address and suspended for the second memory address.

11. The method of claim 10, wherein the first memory address and the second memory address are in a same memory.

12. The method of claim 10, wherein the power management operation includes a refresh operation.

13. The method of claim 10, wherein the first priority is greater than the second priority.

14. The method of claim 13, wherein the second priority corresponds to fault tolerant data.

15. The method of claim 10, wherein:
the first information further indicates a first memory operation, and
the second information further indicates a second memory operation different from the first memory operation, wherein the first memory operation includes a write operation.

16. The method of claim 10, wherein:
the first information is included in the first address, and
the second information is included in the second address.

17. The method of claim 10, further comprising:
generating first tag information and second tag information,
wherein the first tag information is generated from the first information and the second tag information is generated from the second information and wherein the first tag information and second tag information have fewer bits than respective ones of the first information and the second information.

18. The method of claim 17, wherein:
the first information and the first tag information are included or appended to the first memory address, and
the second information and second tag information are included in or appended to the second memory address.

19. The method of claim 10, wherein the power management operation is coincident with an active state of a host device of memory including the first and second memory addresses.

20. A control device comprising:
an interface coupled to a memory configured to store data; and
a controller configured to assign a code corresponding to an address of the memory and to selectively control performance of a power management operation for an area of the memory that includes the memory address, the controller to assign the code based on a status of stored data stored corresponding to the address.
